(19) United States
(12) Patent Application Publication
(10) Pub. No.: US 2026/0144037 A1
(43) Pub. Date: May 21, 2026

(54) SEMICONDUCTOR DEVICE AND SEMICONDUCTOR PACKAGE INCLUDING THE SAME

(71) Applicant: Samsung Electronics Co., Ltd., Suwon-si (KR)

(72) Inventors: Changbo LEE, Suwon-si (KR); Pilkyu KANG, Suwon-si (KR); Eunmi KIM, Suwon-si (KR); Jaewha PARK, Suwon-si (KR); Chanmi LEE, Suwon-si (KR)

(73) Assignee: Samsung Electronics Co., Ltd., Suwon-si (KR)

(21) Appl. No.: 19/295,915

(22) Filed: Aug. 11, 2025

(30) Foreign Application Priority Data
Nov. 19, 2024 (KR) 10-2024-0165606

(51) Int. Cl. H01L 23/48; H01L 25/16; H10B 80/00

(52) U.S. Cl. CPC H10W 20/20; H10B 80/00; H10W 90/00

(57) ABSTRACT

The technical idea of the inventive concepts provides a semiconductor device including a semiconductor substrate, an active layer covering a lower surface of the semiconductor substrate and including a protrusion portion protruding in a direction of the semiconductor substrate from an upper surface of the active layer and a first metal layer covering an upper surface of the protrusion portion, and a through electrode including a plurality of first through electrodes passing through the active layer in a vertical direction and a plurality of second through electrodes passing through the semiconductor substrate in the vertical direction, wherein the plurality of second through electrodes include a first group of second through electrodes respectively connected to the plurality of first through electrodes and a second group of second through electrodes each connected to the first metal layer.

### CROSS-REFERENCE TO RELATED APPLICATION

This application is based on and claims priority under 35 U.S.C. § 119 to Korean Patent Application No. 10-2024-0165606, filed on Nov. 19, 2024, in the Korean Intellectual Property Office, the disclosure of which is incorporated by reference herein in its entirety.

### BACKGROUND

The inventive concepts relate to a semiconductor device and a semiconductor package including the same, and more particularly, to a semiconductor device including a through electrode and a semiconductor package including the same.

Along with the rapid development of the electronics industry and demands of users, electronic devices have become increasingly miniaturized and more lightweight. In accordance with the miniaturization and weight reduction of electronic devices, semiconductor packages used therein also have been increasingly miniaturized and more lightweight, and in addition, the semiconductor packages have been demanded to have high performance, large capacity, and high reliability. To implement the miniaturization, the weight reduction, the high performance, the large capacity, and the high reliability, research and development have been continuously conducted on semiconductor chips including a through silicon via (TSV) structure and semiconductor packages that have a chip-stacked structure in which such semiconductor chips are stacked.

### SUMMARY

The inventive concepts provide a semiconductor device having a first through electrode and a second through electrode respectively formed from the front-side and the back-side of a semiconductor substrate and a semiconductor package including the same.

In addition, the problems to be solved by the technical idea of the inventive concepts are not limited to the problems mentioned above, and other problems could be clearly understood by those of ordinary skill in the art from the description below.

According to an aspect of the inventive concepts, there is provided a semiconductor device including a semiconductor substrate, an active layer covering a lower surface of the semiconductor substrate, the active layer comprising a protrusion portion and a first metal layer, the protrusion portion protruding from an upper surface of the active layer and the first metal layer covering an upper surface of the protrusion portion, a plurality of first through electrodes passing through the active layer in a vertical direction, and a plurality of second through electrodes passing through the semiconductor substrate in the vertical direction, the plurality of second through electrodes including a first group of the plurality of second through electrodes respectively connected to the plurality of first through electrodes; and a second group of the plurality of second through electrodes each connected to the first metal layer.

According to an aspect of the inventive concepts, there is provided a semiconductor device including a semiconductor substrate, an active layer covering a lower surface of the semiconductor substrate, the active layer comprising a protrusion portion and a first metal layer, the protrusion portion protruding from an upper surface of the active layer and the first metal layer covering an upper surface of the protrusion portion, a lower protective layer covering a lower surface of the active layer, an upper protective layer covering an upper surface of the semiconductor substrate, a plurality of first through electrodes passing through the active layer in a vertical direction, a plurality of second through electrodes passing through the semiconductor substrate in the vertical direction, a plurality of lower pads respectively connected to the plurality of first through electrodes and passing through the lower protective layer, and a plurality of upper pads respectively connected to the plurality of second through electrodes and passing through the upper protective layer, wherein the plurality of second through electrodes include a first group of the plurality of second through electrodes respectively connected to the plurality of first through electrodes and configured to transfer a signal and a second group of the plurality of second through electrodes each connected to the first metal layer and configured to transfer power.

According to an aspect of the inventive concepts, there is provided a semiconductor package including a base chip, a plurality of memory chips\on the base chip, and a sealing material sealing the plurality of memory chips on the base chip, wherein each of the plurality of memory chips includes a semiconductor substrate, an active layer covering a lower surface of the semiconductor substrate, the active layer comprising a protrusion portion and a first metal layer, the protrusion portion protruding from an upper surface of the active layer and the first metal layer covering an upper surface of the protrusion portion, a plurality of first through electrodes passing through the active layer in a vertical direction, and a plurality of second through electrodes passing through the semiconductor substrate in the vertical direction, and the plurality of second through electrodes include a first group of the plurality of second through electrodes respectively connected to the plurality of first through electrodes and configured to transfer a signal and a second group of the plurality of second through electrodes each connected to the first metal layer and configured to transfer power.

According to an aspect of the inventive concepts, there is provided a method of forming a semiconductor package, the method including forming an active layer on a first surface of a semiconductor substrate such that a protrusion portion of the active layer protrudes into the semiconductor substrate, and a first metal layer is between the protrusion portion and the semiconductor substrate; forming first upper protective layer onto a second surface of the semiconductor substrate, the second surface opposite to the first surface; forming a plurality of trenches in the semiconductor substrate such that trenches penetrate the semiconductor substrate and the first upper protective layer, and such that a subset of the trenches exposed the protrusion portion of the first metal layer; and forming a plurality of through electrodes in the trenches.

The forming a plurality of through electrodes may include forming an insulating layer on the sidewalls of the trenches; covering the insulating layer and a bottom surface of the trenches with a seed layer; and forming the plurality of through electrodes using the seed layer as an electrode in an electroplating operation.

### BRIEF DESCRIPTION OF THE DRAWINGS

Embodiments of the inventive concepts will be more clearly understood from the following detailed description taken in conjunction with the accompanying drawings in which:

FIG. 1 is a cross-sectional view schematically illustrating a semiconductor device according to at least one example embodiment;

FIG. 2 is an enlarged cross-sectional view of portion “EX1” of FIG. 1;

FIG. 3 is an enlarged cross-sectional view of portion “EX2” of FIG. 1;

FIGS. 4A to 4E are enlarged cross-sectional views of the portion “EX2” of FIG. 1 according to some example embodiments;

FIGS. 5 to 10 are cross-sectional views sequentially illustrating a method of manufacturing a semiconductor device, according to at least one example embodiment; and

FIG. 11 is a cross-sectional view schematically illustrating a semiconductor package according to at least one example embodiment.

### DETAILED DESCRIPTION OF THE EMBODIMENTS

Hereinafter, embodiments are described in detail with reference to the accompanying drawings. Like reference numerals in the drawings denote like elements, and thus their repetitive description will be omitted. Additionally, spatially relative terms, such as above, below, etc. are represented herein based on the direction illustrated in the drawings and may be represented otherwise when the orientation of the corresponding object changes. In other words, such spatially relative terms are intended to encompass different orientations of the device in use or operation in addition to the orientation depicted in the figures, such that the device may be otherwise oriented (rotated 90 degrees or at other orientations) and the spatially relative terms used herein interpreted accordingly.

Herein, when the terms “about” or “substantially” are used in this specification in connection with a numerical value and/or geometric term, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

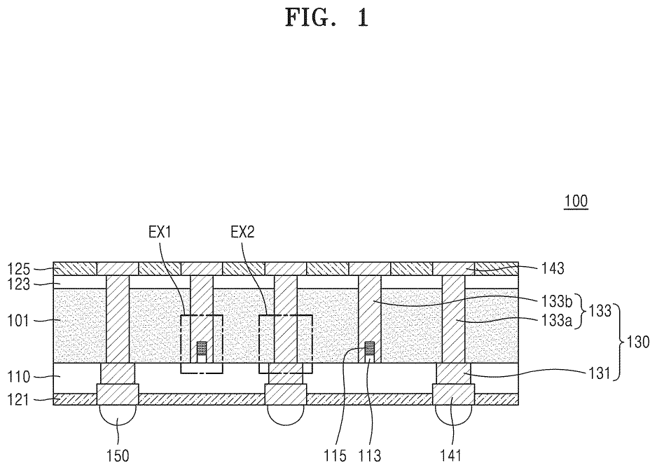

FIG. 1 is a cross-sectional view schematically illustrating a semiconductor device 100 according to at least one example embodiment.

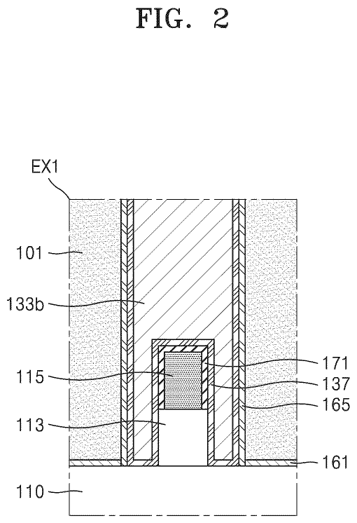

FIG. 2 is an enlarged cross-sectional view of portion “EX1” of FIG. 1.

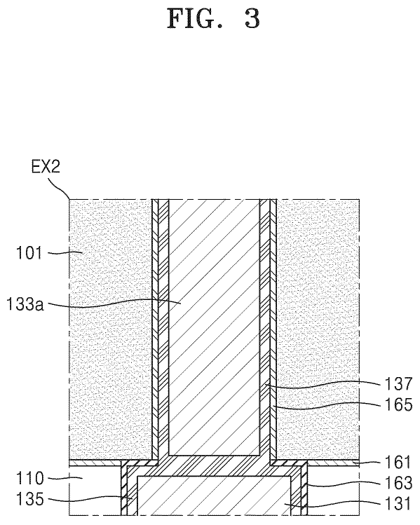

FIG. 3 is an enlarged cross-sectional view of portion “EX2” of FIG. 1.

Referring to FIGS. 1 to 3, according to at least one example embodiment, the semiconductor device 100 includes a semiconductor substrate 101, an active layer 110, a lower protective layer 121, a first upper protective layer 123, a second upper protective layer 125, a through electrode 130, a lower pad 141, an upper pad 143, and a connection terminal 150.

In some example embodiments, the semiconductor substrate 101 may constitute a body of the semiconductor device 100 and include an elemental and/or a compound semiconductor material, such as silicon (Si), germanium (Ge), silicon germanium (SiGe), silicon carbide (SiC), gallium phosphide (GaP), gallium arsenide (GaAs), gallium antimonide (GaSb), indium phosphide (InP), and/or the like. For example, in at least example, the semiconductor substrate 101 may be a silicon substrate. In some embodiments, the semiconductor substrate 101 may include a silicon-on-insulator (SOI) substrate or a germanium-on-insulator (GOI) substrate. For example, the semiconductor substrate 101 may include a buried oxide (BOX) layer.

In some example embodiments, the active layer 110 may be provided beneath the semiconductor substrate 1101 and include an integrated circuit layer and a wiring layer. For example, the integrated circuit layer may include various active devices and/or passive devices, such as a transistor, logic devices, capacitors, memory devices, a system large scale integration (LSI) chip, a complementary metal-insulator-semiconductor (CMOS) imaging sensor (CIS), a micro-electro-mechanical system (MEMS), and/or the like.

In some example embodiments, the transistor may include a field effect transistor (FET), such as a bipolar junction transistor (BJT), a planar FET, or a FinFET. The logic devices may include, for example, an AND, a NAND, an OR, a NOR, an exclusive OR (XOR), exclusive NOR (XNOR), an inverter (INV), an adder (ADD), a delay (DLY), filter (FIL), a multiplexer (MXT/MXIT), an OR/AND/INV (OAI), an AND/OR (AO), an AND/OR/INV (AOI), a D flip-flop, a reset flip-flop, a master-slave flip-flop, a latch, a counter, a buffer device, and/or the like. The logic devices may perform various kinds of signal processing, such as analog signal processing, analog-to-digital (A/D) conversion, and control.

In some example embodiments, the memory devices may include flash memory, dynamic random access memory (DRAM) or static random access memory (SRAM), electrically erasable programmable read-only memory (EEPROM), phase-change random access memory (PRAM), magnetoresistive random access memory (MRAM), ferroelectric random access memory (FeRAM), resistive random access memory (RRAM), and the like.

In some example embodiments, the integrated circuit layer of the active layer 110 of the semiconductor device 100 may include a plurality of memory devices. For example, the integrated circuit layer may include volatile memory devices, such as DRAM and SRAM, or non-volatile memory devices, such as PRAM, MRAM, FeRAM, and RRAM. In some example embodiments, the integrated circuit layer of the active layer 110 of the semiconductor device 100 may include DRAM devices. Accordingly, the semiconductor device 100 may be a DRAM chip. Alternatively, the semiconductor device 100 may be a DRAM chip for high bandwidth memory (HBM). However, the semiconductor device 100 of the inventive concepts are not limited to the DRAM chip or the DRAM chip for HBM.

In some example embodiments, the wiring layer of the active layer 110 may be provided under the integrated circuit layer. The wiring layer may connect devices to each other or connect the devices to the connection terminal 150. The wiring layer may include an interlayer insulating layer and wirings. The wirings may be connected to the devices of the integrated circuit layer, the through electrode 130, or the connection terminal 150 via a contact or a via. The wirings may be provided as two or more layers. Wirings in different layers may be isolated by the interlayer insulating layer and connected to each other through the via.

In some example embodiments, the active layer 110 may include a protrusion portion 113 protruding in a direction towards the semiconductor substrate 101 from the upper surface of the active layer 110 and a first metal layer 115 covering the upper surface of the protrusion portion 113. Herein, the first metal layer 115 is configured to supply power to the semiconductor substrate 101. For example, the first metal layer 115 may also be referred to as a power rail or a power pad. The first metal layer 115 may include an electrically conductive metal, such as at least one of copper (Cu), aluminum (Al), silver (Ag), nickel (Ni), palladium (Pd), platinum (Pt), gold (Au), and/or the like.

In some example embodiments, the lower protective layer 121 may be disposed on the lower surface of the semiconductor device 100. An upper protective layer may be disposed on the upper surface of the semiconductor device 100. The upper protective layer may have a multi-layer structure including the first upper protective layer 123 and the second upper protective layer 125. The first upper protective layer 123 may cover the upper surface of the semiconductor device 100, and the second upper protective layer 125 may cover the upper surface of the first upper protective layer 123. Although FIG. 1 shows that the lower protective layer 121 has a single-layer structure, the lower protective layer 121 is not limited thereto and may have a multi-layer structure. For example, each of the lower protective layer 121 and the upper protective layer may include two or more insulating layers. For example, each of the lower protective layer 121, the first upper protective layer 123, and the second upper protective layer 125 may include at least one of an oxide film, a nitride film, a carbide film, a polymer, and/or a combination thereof.

In some example embodiments, the lower pad 141 may have a structure passing through the lower protective layer 121. For example, the lower pad 141 may have a structure fully or partially passing through the lower protective layer 121. The lower pad 141 may have a structure buried in the lower protective layer 121 and be exposed from the lower surface of the lower protective layer 121. The lower pad 141 may be connected to the wirings of the wiring layer of the active layer 110 or to the through electrode 130. In addition, the lower pad 141 may be connected to the connection terminal 150.

In some example embodiments, the upper pad 143 may have a structure passing through the second upper protective layer 125. For example, the upper pad 143 may have a structure fully or partially passing through the second upper protective layer 125. Herein, the upper pad 143 may have a structure partially passing through the first upper protective layer 123. The upper pad 143 may have a structure buried in the second upper protective layer 125 and be exposed from the upper surface of the second upper protective layer 125. The upper pad 143 may be directly connected to the through electrode 130. That is, the lower surface of the upper pad 143 may be in contact with the upper surface of the through electrode 130. The upper pad 143 and the lower pad 141 may each include a conductive material, such as a zero-band gap material and/or the like.

In some example embodiments, the connection terminal 150 may be disposed on the lower surface of the semiconductor device 100. Particularly, the connection terminal 150 may be disposed on the lower pad 141 of the lower surface of the semiconductor device 100. The connection terminal 150 may include a solder. The solder may include, for example, one or more of tin (Sn), indium (In), bismuth (Bi), antimony (Sb), copper (Cu), silver (Ag), zinc (Zn), and/or an alloy thereof. For example, the solder may include Sn, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, and/or the like. In some embodiments, the connection terminal 150 may be referred to as a bump, a solder, a solder bump, or the like. In some embodiments, the connection terminal 150 may further include a pillar, and the solder may be disposed on the pillar. The pillar may include, for example, nickel (Ni), Cu, palladium (Pd), platinum (Pt), gold (Au), and/or a combination thereof. In some embodiments, the pillar may function as a chip pad and include Cu. Accordingly, the pillar may be referred to as a bump pad, a Cu pad, a Cu pillar, or the like. When the pillar functions as a chip pad, a chip pad, e.g., the lower pad 141, on the lower surface of the semiconductor device 100 may not be formed.

In some example embodiments, the through electrode 130 may include a plurality of first through electrodes 131 and a plurality of second through electrodes 133. Each of the plurality of first through electrodes 131 may pass through the active layer 110 in the vertical direction. The lower surface of a first through electrode 131 may be connected to the upper surface of the lower pad 141, and the upper surface of the first through electrode 131 may be connected to the lower surface of a second through electrode 133. The second through electrode 133 may pass through the semiconductor substrate 101 in the vertical direction. Herein, the second through electrode 133 may pass through the first upper protective layer 123, but the inventive concepts are not limited thereto. The upper surface of the second through electrode 133 may be connected to the lower surface of the upper pad 143, and the lower surface of the second through electrode 133 may be connected to the upper surface of the first through electrode 131.

In some example embodiments, the plurality of second through electrodes 133 may include a first group of second through electrodes 133a and a second group of second through electrodes 133b. A second through electrode 133a in the first group may be connected to the first through electrode 131. That is, the lower surface of the second through electrode 133a in the first group may be in contact with the upper surface of the first through electrode 131. A second through electrode 133b in the second group may be connected to the first metal layer 115. That is, the second through electrode 133b in the second group may be in contact with the first metal layer 115. The lower surface of the second through electrode 133a in the first group may be coplanar with the lower surface of the second through electrode 133b in the second group, but the inventive concepts are not limited thereto. The vertical level of the lower surface of the second through electrode 133a in the first group may be different from the vertical level of the lower surface of the second through electrode 133b in the second group. For example, the vertical level of the lower surface of the second through electrode 133a in the first group may be higher than the vertical level of the lower surface of the second through electrode 133b in the second group.

In some example embodiments, the second through electrode 133b in the second group may cover the upper surface and the side surface of the first metal layer 115. In addition, the second through electrode 133b in the second group may cover the side surface of the protrusion portion 113 and a portion of the upper surface of the active layer 110. The lower surface of the second through electrode 133b in the second group may have a recessed shape corresponding to the shapes of the protrusion portion 113 and the first metal layer 115.

Referring to FIGS. 1, 2, and 3, the through electrode 130 may further include a first seed layer 135 and a second seed layer 137. Particularly, the first through electrode 131 may include the first seed layer 135, and the second through electrode 133 may include the second seed layer 137. The first seed layer 135 may surround the first through electrode 131, and the second seed layer 137 may surround the second through electrode 133. For example, the first seed layer 135 may cover the upper surface and the side surface of the first through electrode 131, and the second seed layer 137 may cover the lower surface and the side surface of the second through electrode 133.

In some example embodiments, the second seed layer 137 may cover the lower surface and the side surface of the second through electrode 133b in the second group. The second seed layer 137 may cover the upper surface and the side surface of the first metal layer 115. In addition, the second seed layer 137 may cover the side surface of the protrusion portion 113 and a portion of the upper surface of the active layer 110. In the second through electrode 133b in the second group, the second seed layer 137 may have a recessed shape corresponding to the shapes of the protrusion portion 113 and the first metal layer 115.

In some example embodiments, a barrier layer 171 may be provided between the second through electrode 133b in the second group and the first metal layer 115. The barrier layer 171 may be spaced apart from the second through electrode 133b in the second group with the second seed layer 137 therebetween. In addition, the second seed layer 137 and the second through electrode 133b in the second group may be spaced apart from the first metal layer 115 with the barrier layer 171 therebetween. That is, the barrier layer 171 may cover the upper surface and the side surface of the first metal layer 115.

In some example embodiments, a first insulating layer 161 may be provided between the semiconductor substrate 101 and the active layer 110. The first insulating layer 161 may be formed in the interface of the semiconductor substrate 101 and the active layer 110. A second insulating layer 163 may be provided between the first through electrode 131 and the active layer 110. The second insulating layer 163 may be formed in the interface of the first seed layer 135 and the active layer 110. A third insulating layer 165 may be provided between the second through electrode 133a in the first group and the semiconductor substrate 101 and between the second through electrode 133b in the second group and the semiconductor substrate 101. The third insulating layer 165 may be formed in the interface of the second seed layer 137 and the semiconductor substrate 101. Herein, the respective thicknesses of the first insulating layer 161, the second insulating layer 163, and the third insulating layer 165 may be different from each other, but the inventive concepts are not limited thereto. Each of the first insulating layer 161, the second insulating layer 163, and the third insulating layer 165 may include oxide, but the embodiments are not limited thereto.

In some example embodiments, the upper surfaces of the plurality of first through electrodes 131 may be coplanar with the upper surface of the active layer 110. In addition, the lower surfaces of the plurality of second through electrodes 133 may be coplanar with the lower surface of the semiconductor substrate 101. Particularly, the upper surface of the first seed layer 135 may be coplanar with the upper surface of the active layer 110, and the lower surface of the second seed layer 137 may be coplanar with the lower surface of the semiconductor substrate 101. That is, the interface of the semiconductor substrate 101 and the active layer 110 may be coplanar with the interface of the first seed layer 135 and the second seed layer 137, but the inventive concepts are not limited thereto.

In some example embodiments, the width of each of the plurality of first through electrodes 131 in the horizontal direction may be different from the width of each of the plurality of second through electrodes 133 in the horizontal direction. The width of the first through electrode 131 in the horizontal direction may be greater than the width of the second through electrode 133 in the horizontal direction, but the inventive concepts are not limited thereto. In addition, the width of the second through electrode 133a in the first group in the horizontal direction may be substantially the same as the width of the second through electrode 133b in the second group in the horizontal direction, but the inventive concepts are not limited thereto. For example, the width of the second through electrode 133a in the first group in the horizontal direction may be different from the width of the second through electrode 133b in the second group in the horizontal direction.

In some example embodiments, the side surface of the first through electrode 131 may not be coplanar with the side surface of the second through electrode 133. Because the width of the first through electrode 131 in the horizontal direction is different from the width of the second through electrode 133 in the horizontal direction, a step difference in the horizontal direction may be formed at the interface of the first through electrode 131 and the second through electrode 133. As shown in FIG. 3, because the width of the first through electrode 131 in the horizontal direction is greater than the width of the second through electrode 133a in the first group in the horizontal direction, a step difference in the horizontal direction may be formed at the interface of the first through electrode 131 and the second through electrode 133a in the first group. Accordingly, a step difference in the horizontal direction may also be formed at the interface of the first seed layer 135 and the second seed layer 137. For example, the first seed layer 135 may have a shape relatively protruding in the horizontal direction, and the second seed layer 137 may have a shape relatively recessed in the horizontal direction.

In some example embodiments, a thick seed layer may be formed at the interface of the first through electrode 131 and the second through electrode 133a in the first group. For example, a thick seed layer may be formed at a portion where the first seed layer 135 overlaps the second seed layer 137 in the vertical direction in the interface of the first through electrode 131 and the second through electrode 133a in the first group.

In some example embodiments, the second through electrode 133a in the first group may transfer a signal. The second through electrode 133a in the first group may be connected to the first through electrode 131 and function as a path for transferring a signal. The second through electrode 133b in the second group may transfer power. The second through electrode 133b in the second group may be connected to the first metal layer 115 and function as a path for transferring power.

Because a semiconductor device according to a comparative example has one through electrode formed on the front-side of a semiconductor substrate, process difficulty may increase as the pitch of the through electrode decreases and the depth of the through electrode increases. However, in the semiconductor device 100 of the inventive concepts, by respectively forming the first through electrode 131 and the second through electrode 133 from the front-side and the back-side of the semiconductor substrate 101, the through electrode 130 of which the pitch decreases and the depth increases may be formed. Accordingly, the process cost and process difficulty of the semiconductor device 100 may be reduced, and the electrical performance of the semiconductor device 100 may be improved.

In addition, by forming, from the back-side of the semiconductor substrate 101, the second group of second through electrodes 133b for transferring power, the degree of freedom in the design of the first group of second through electrodes 133a for transferring a signal may increase.

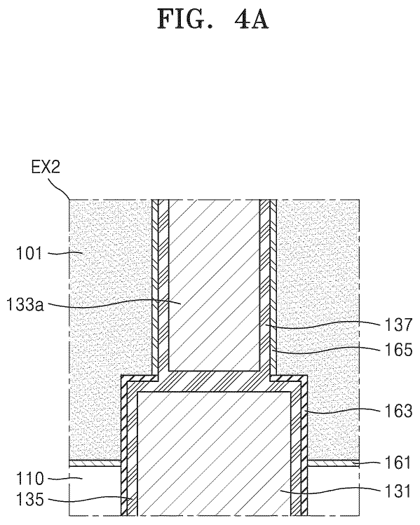

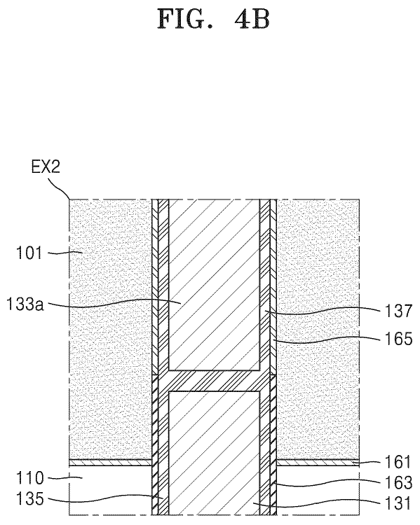

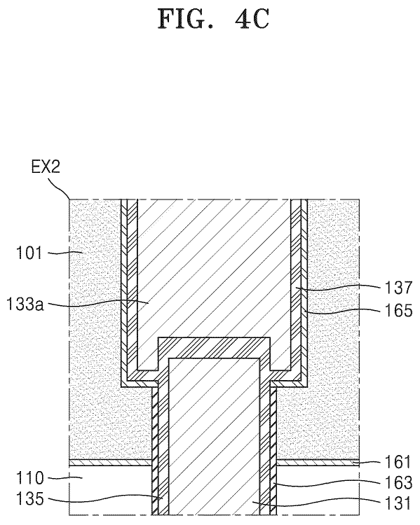

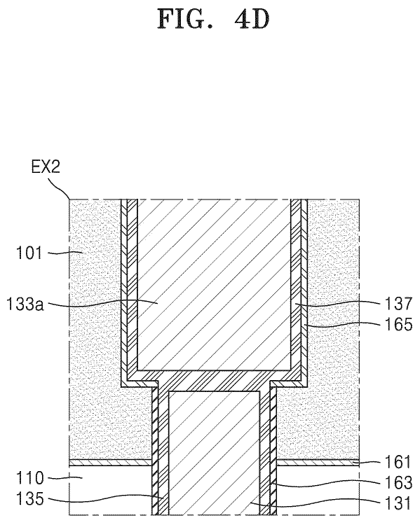

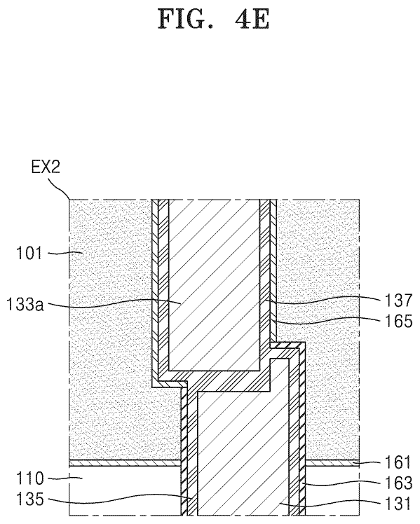

FIGS. 4A to 4E are enlarged cross-sectional views of the portion “EX2” of FIG. 1 according to some example embodiments.

FIGS. 4A to 4E are enlarged cross-sectional views illustrating the interface of the first through electrode 131 and the second through electrode 133a in the first group in semiconductor devices according to some embodiments, wherein the description made with respect to the semiconductor device 100 with reference to FIGS. 1 to 3 is omitted, and differences between the semiconductor devices and the semiconductor device 100 are mainly described.

Referring to FIG. 4A, the vertical level of the upper surface of the first through electrode 131 may be higher than the vertical level of the upper surface of the active layer 110. In addition, the vertical level of the lower surface of the second through electrode 133a in the first group may be higher than the vertical level of the lower surface of the semiconductor substrate 101. The plurality of first through electrodes 131 may extend in the vertical direction to pass through a portion of the semiconductor substrate 101. Particularly, the vertical level of the upper surface of the first seed layer 135 may be higher than the vertical level of the upper surface of the active layer 110, and the vertical level of the lower surface of the second seed layer 137 may be higher than the vertical level of the lower surface of the semiconductor substrate 101. That is, the interface of the semiconductor substrate 101 and the active layer 110 may be different from the interface of the first seed layer 135 and the second seed layer 137. The vertical level of the interface of the first seed layer 135 and the second seed layer 137 may be higher than the vertical level of the interface of the semiconductor substrate 101 and the active layer 110. However, the inventive concepts are not limited thereto, and the vertical level of the interface of the first seed layer 135 and the second seed layer 137 may be lower than the vertical level of the interface of the semiconductor substrate 101 and the active layer 110.

Referring to FIG. 4B, the width of the first through electrode 131 in the horizontal direction may be the same as the width of the second through electrode 133a in the first group in the horizontal direction. The side surface of the first through electrode 131 may be coplanar with the side surface of the second through electrode 133a in the first group. In addition, the side surface of the first seed layer 135 may be coplanar with the side surface of the second seed layer 137. In addition, the side surface of the second insulating layer 163 may also be coplanar with the side surface of the third insulating layer 165. Because the width of the first through electrode 131 in the horizontal direction is the same as the width of the second through electrode 133a in the first group in the horizontal direction, the interface of the first through electrode 131 and the second through electrode 133a in the first group may have a flat shape without a step difference.

In some example embodiments, the vertical level of the upper surface of the first through electrode 131 may be higher than the vertical level of the upper surface of the active layer 110. In addition, the vertical level of the lower surface of the second through electrode 133a in the first group may be higher than the vertical level of the lower surface of the semiconductor substrate 101. The plurality of first through electrodes 131 may extend in the vertical direction to pass through a portion of the semiconductor substrate 101. Particularly, the vertical level of the upper surface of the first seed layer 135 may be higher than the vertical level of the upper surface of the active layer 110, and the vertical level of the lower surface of the second seed layer 137 may be higher than the vertical level of the lower surface of the semiconductor substrate 101. That is, the interface of the semiconductor substrate 101 and the active layer 110 may be different from the interface of the first seed layer 135 and the second seed layer 137. The vertical level of the interface of the first seed layer 135 and the second seed layer 137 may be higher than the vertical level of the interface of the semiconductor substrate 101 and the active layer 110. However, the inventive concepts are not limited thereto, and the vertical level of the interface of the first seed layer 135 and the second seed layer 137 may be lower than the vertical level of the interface of the semiconductor substrate 101 and the active layer 110.

Referring to FIG. 4C, the width of the first through electrode 131 in the horizontal direction may be different from the width of the second through electrode 133a in the first group in the horizontal direction. The width of the first through electrode 131 in the horizontal direction may be less than the width of the second through electrode 133a in the first group in the horizontal direction.

In some example embodiments, the side surface of the first through electrode 131 may not be coplanar with the side surface of the second through electrode 133a in the first group. Because the width of the first through electrode 131 in the horizontal direction is different from the width of the second through electrode 133a in the first group in the horizontal direction, a step difference in the horizontal direction may be formed at the interface of the first through electrode 131 and the second through electrode 133a in the first group. Because the width of the first through electrode 131 in the horizontal direction is less than the width of the second through electrode 133a in the first group in the horizontal direction, a step difference in the horizontal direction may be formed at the interface of the first through electrode 131 and the second through electrode 133a in the first group. Accordingly, a step difference in the horizontal direction may also be formed at the interface of the first seed layer 135 and the second seed layer 137. For example, the second seed layer 137 may have a shape relatively protruding in the horizontal direction, and the first seed layer 135 may have a shape relatively recessed in the horizontal direction.

In some example embodiments, the second through electrode 133a in the first group may surround a portion of the first through electrode 131. The second through electrode 133a in the first group may cover the upper surface and a portion of the side surface of the first through electrode 131. The first through electrode 131 may have a shape protruding in the direction of the second through electrode 133a in the first group, and the second through electrode 133a in the first group may include a recessed portion surrounding the first through electrode 131.

In some example embodiments, the vertical level of the upper surface of the first through electrode 131 may be higher than the vertical level of the upper surface of the active layer 110. In addition, the vertical level of the lower surface of the second through electrode 133a in the first group may be higher than the vertical level of the lower surface of the semiconductor substrate 101. The plurality of first through electrodes 131 may extend in the vertical direction to pass through a portion of the semiconductor substrate 101. Particularly, the vertical level of the upper surface of the first seed layer 135 may be higher than the vertical level of the upper surface of the active layer 110, and the vertical level of the lower surface of the second seed layer 137 may be higher than the vertical level of the lower surface of the semiconductor substrate 101. That is, the interface of the semiconductor substrate 101 and the active layer 110 may be different from the interface of the first seed layer 135 and the second seed layer 137. The vertical level of the interface of the first seed layer 135 and the second seed layer 137 may be higher than the vertical level of the interface of the semiconductor substrate 101 and the active layer 110. However, the inventive concepts are not limited thereto, and the vertical level of the interface of the first seed layer 135 and the second seed layer 137 may be lower than the vertical level of the interface of the semiconductor substrate 101 and the active layer 110.

Referring to FIG. 4D, the width of the first through electrode 131 in the horizontal direction may be different from the width of the second through electrode 133a in the first group in the horizontal direction. The width of the first through electrode 131 in the horizontal direction may be less than the width of the second through electrode 133a in the first group in the horizontal direction.

In some example embodiments, the side surface of the first through electrode 131 may not be coplanar with the side surface of the second through electrode 133a in the first group. Because the width of the first through electrode 131 in the horizontal direction is different from the width of the second through electrode 133a in the first group in the horizontal direction, a step difference in the horizontal direction may be formed at the interface of the first through electrode 131 and the second through electrode 133a in the first group. Because the width of the first through electrode 131 in the horizontal direction is less than the width of the second through electrode 133a in the first group in the horizontal direction, a step difference in the horizontal direction may be formed at the interface of the first through electrode 131 and the second through electrode 133a in the first group. Accordingly, a step difference in the horizontal direction may also be formed at the interface of the first seed layer 135 and the second seed layer 137. For example, the second seed layer 137 may have a shape relatively protruding in the horizontal direction, and the first seed layer 135 may have a shape relatively recessed in the horizontal direction.

In some example embodiments, the vertical level of the upper surface of the first through electrode 131 may be higher than the vertical level of the upper surface of the active layer 110. In addition, the vertical level of the lower surface of the second through electrode 133a in the first group may be higher than the vertical level of the lower surface of the semiconductor substrate 101. The plurality of first through electrodes 131 may extend in the vertical direction to pass through a portion of the semiconductor substrate 101. Particularly, the vertical level of the upper surface of the first seed layer 135 may be higher than the vertical level of the upper surface of the active layer 110, and the vertical level of the lower surface of the second seed layer 137 may be higher than the vertical level of the lower surface of the semiconductor substrate 101. That is, the interface of the semiconductor substrate 101 and the active layer 110 may be different from the interface of the first seed layer 135 and the second seed layer 137. The vertical level of the interface of the first seed layer 135 and the second seed layer 137 may be higher than the vertical level of the interface of the semiconductor substrate 101 and the active layer 110. However, the inventive concepts are not limited thereto, and the vertical level of the interface of the first seed layer 135 and the second seed layer 137 may be lower than the vertical level of the interface of the semiconductor substrate 101 and the active layer 110.

Referring to FIG. 4E, the central axis of the second through electrode 133a in the first group in the vertical direction may not be aligned with the central axis of the first through electrode 131 in the vertical direction such that the second through electrode 133a in the first group is obliquely arranged with respect to the first through electrode 131 in the vertical direction. That is, the central axis of the second through electrode 133a in the first group in the vertical direction may mismatch the central axis of the first through electrode 131 in the vertical direction. For example, a portion of the lower surface of the second through electrode 133a in the first group may be in contact with a portion of the upper surface of the first through electrode 131. In addition, a portion of the side surface of the second through electrode 133a in the first group may be in contact with a portion of the side surface of the first through electrode 131. The first through electrode 131 may include a portion protruding in the direction of the second through electrode 133a in the first group, and the protruding portion may cover the portion of the side surface of the second through electrode 133a in the first group.

In some example embodiments, the width of the first through electrode 131 in the horizontal direction may be the same as the width of the second through electrode 133a in the first group in the horizontal direction. However, because the central axis of the second through electrode 133a in the first group in the vertical direction is not aligned with the central axis of the first through electrode 131 in the vertical direction, a step difference in the horizontal direction may be formed at the interface of the first through electrode 131 and the second through electrode 133a in the first group. That is, the side surface of the first through electrode 131 may not be coplanar with the side surface of the second through electrode 133a in the first group.

In some example embodiments, the vertical level of the upper surface of the first through electrode 131 may be higher than the vertical level of the upper surface of the active layer 110. In addition, the vertical level of the lower surface of the second through electrode 133a in the first group may be higher than the vertical level of the lower surface of the semiconductor substrate 101. The plurality of first through electrodes 131 may extend in the vertical direction to pass through a portion of the semiconductor substrate 101. Particularly, the vertical level of the upper surface of the first seed layer 135 may be higher than the vertical level of the upper surface of the active layer 110, and the vertical level of the lower surface of the second seed layer 137 may be higher than the vertical level of the lower surface of the semiconductor substrate 101. That is, the interface of the semiconductor substrate 101 and the active layer 110 may be different from the interface of the first seed layer 135 and the second seed layer 137. The vertical level of the interface of the first seed layer 135 and the second seed layer 137 may be higher than the vertical level of the interface of the semiconductor substrate 101 and the active layer 110. However, the inventive concepts are not limited thereto, and the vertical level of the interface of the first seed layer 135 and the second seed layer 137 may be lower than the vertical level of the interface of the semiconductor substrate 101 and the active layer 110.

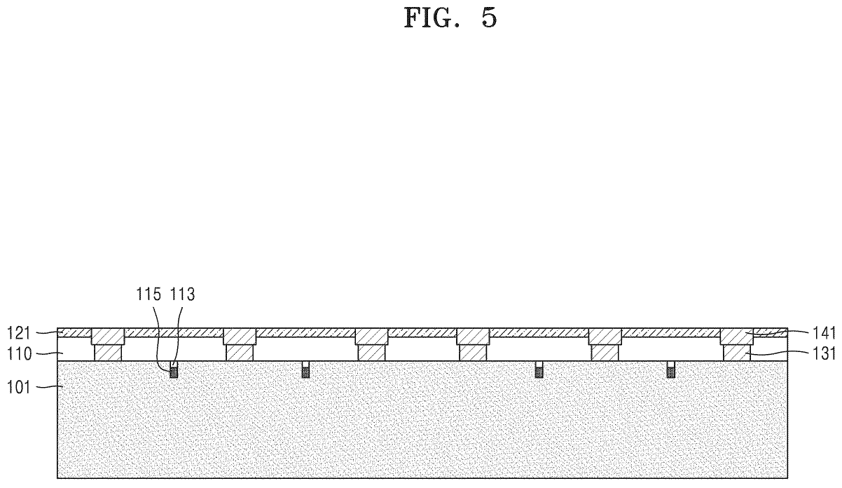

FIGS. 5 to 10 are cross-sectional views sequentially illustrating a method of manufacturing the semiconductor device 100, according to at least one example embodiment. The description of FIGS. 5 to 10 is made with reference to FIG. 1, and the description made with reference to FIGS. 1 to 3 is simply repeated or omitted.

Referring to FIG. 5, the active layer 110 may be formed on the front-side of the semiconductor substrate 101. Herein, the semiconductor substrate 101 may include a semiconductor such as Si, and the active layer 110 may include the integrated circuit layer and the wiring layer. The active layer 110 may include the protrusion portion 113 protruding in the direction of the semiconductor substrate 101 from the front-side of the active layer 110 and the first metal layer 115 covering the upper surface of the protrusion portion 113. In addition, the barrier layer 171 (see FIG. 2) may be formed to cover the upper surface and the side surface of the first metal layer 115. Herein, the first metal layer 115 may be a power rail or a power pad for supplying power to the semiconductor substrate 101.

Thereafter, the first through electrode 131 passing through the active layer 110 in the vertical direction may be formed. After forming a trench passing through the active layer 110, the second insulating layer 163 (see FIG. 3) covering the sidewall of the trench may be formed. Thereafter, the first seed layer 135 (see FIG. 3) covering the second insulating layer 163 (see FIG. 3) and the trench may be formed, and the first through electrode 131 may be formed from the first seed layer 135 (see FIG. 3) through electroplating and chemical mechanical polishing (CMP). In this case, the first through electrode 131 may be in contact with the front-side of the semiconductor substrate 101, but the inventive concepts are not limited thereto. For example, the first through electrode 131 may be formed to pass through a portion of the semiconductor substrate 101 in the vertical direction. As a reference, the through electrode 130 may be classified into a via-first structure formed before the integrated circuit layer is formed, a via-middle structure formed after the integrated circuit layer is formed and before the wiring layer is formed, and a via-last structure formed after the wiring layer is formed. The semiconductor device 100 of the inventive concepts may include, for example, the through electrode 130 that has the via-middle structure but is not limited thereto. For example, the semiconductor device 100 of the inventive concepts may include the through electrode 130 that has the via-first or via-last structure.

Thereafter, the lower protective layer 121 covering the first through electrode 131 and the active layer 110 may be formed. After forming the lower protective layer 121, the lower pad 141 passing through the lower protective layer 121 and connected to the first through electrode 131 may be formed.

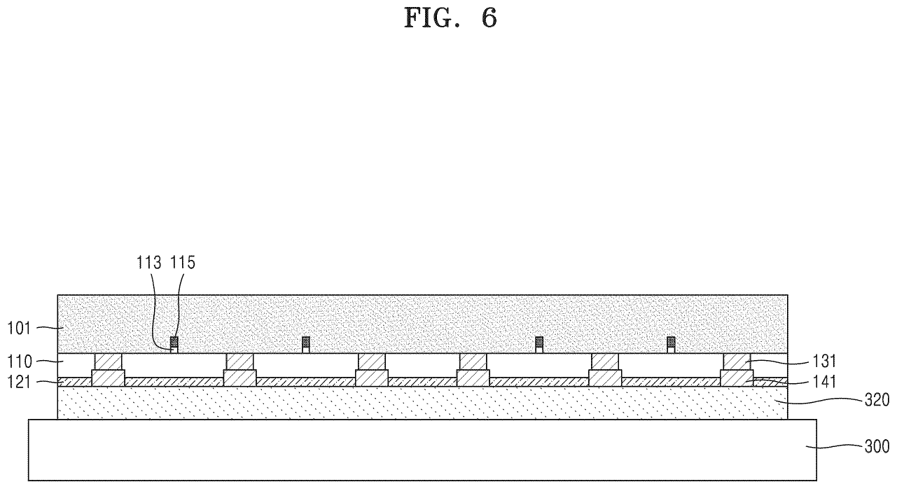

Referring to FIG. 6, the structure of FIG. 5 may be turned over and then adhered and fixed to a carrier substrate 300 through an adhesive layer 320. Thereafter, an Si-recess process on the semiconductor substrate 101 may be performed to remove a portion of the back-side of the semiconductor substrate 101. The Si-recess process may be performed through a dry-etch process. However, in some embodiments, the Si-recess process may use a wet-etch process. By the Si-recess process, the thickness of the semiconductor substrate 101 may decrease.

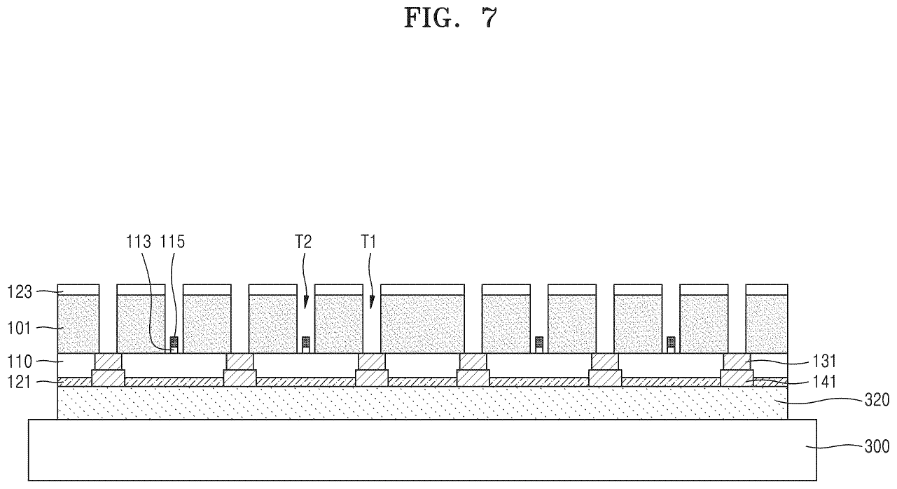

Referring to FIG. 7, the first upper protective layer 123 may be formed on the semiconductor substrate 101. The first upper protective layer 123 may be formed through a chemical vapor deposition (CVD) process, but the inventive concepts are not limited thereto.

Thereafter, a mask pattern may be formed on the first upper protective layer 123 and used as an etching mask to form a plurality of first trenches T1 and a plurality of second trenches T2. In a process of forming the plurality of first trenches T1 and the plurality of second trenches T2, a portion of the first insulating layer 161 (see FIG. 2) existing at the interface of the semiconductor substrate 101 and the active layer 110 may be removed. Each of the plurality of first trenches T1 may expose a portion of the upper surface of the first through electrode 131. Each of the plurality of second trenches T2 may expose the protrusion portion 113, the first metal layer 115, and a portion of the upper surface of the active layer 110. Herein, the width of a first trench T1 in the horizontal direction may be the same as the width of a second trench T2 in the horizontal direction, but the inventive concepts are not limited thereto.

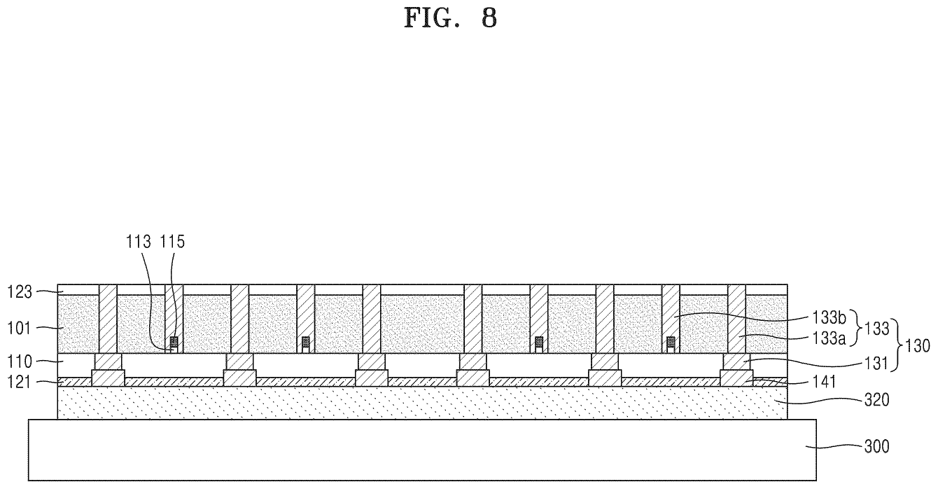

Referring to FIG. 8, the plurality of second through electrodes 133 respectively filling the plurality of first trenches T1 and the plurality of second trenches T2 may be formed. The second through electrode 133 may be formed through a physical vapor deposition (PVD) process and electroplating, but the inventive concepts are not limited thereto.

For example, after forming the third insulating layer 165 (see FIG. 3) covering the sidewall of the first trench T1 (see FIG. 7), the second seed layer 137 (see FIG. 3) covering the third insulating layer 165 (see FIG. 3) and the lower surface of the first trench T1 (see FIG. 7) may be formed. Thereafter, the second through electrode 133a in the first group may be formed from the second seed layer 137 through electroplating and a CMP process. In this case, the second through electrode 133a in the first group may be connected to the first through electrode 131.

In addition, after forming the third insulating layer 165 (see FIG. 2) covering the sidewall of the second trench T2 (see FIG. 7), the second seed layer 137 (see FIG. 2) covering the third insulating layer 165 (see FIG. 2) and the bottom surface of the second trench T2 (see FIG. 7) may be formed. In this case, the second seed layer 137 (see FIG. 2) may be formed to cover the side surface of the protrusion portion 113 and the side surface and the upper surface of the first metal layer 115. Thereafter, the second through electrode 133b in the second group may be formed from the second seed layer 137 (see FIG. 2) through electroplating and a CMP process. In this case, the second through electrode 133b in the second group may be connected to the first metal layer 115.

In the semiconductor device 100 of the inventive concepts, by respectively forming the first through electrode 131 and the second through electrode 133 from the front-side and the back-side of the semiconductor substrate 101, the through electrode 130 of which the pitch decreases and the depth increases may be formed. Accordingly, the process cost and process difficulty of the semiconductor device 100 may be reduced, and the electrical performance of the semiconductor device 100 may be improved.

In addition, by forming, from the back-side of the semiconductor substrate 101, the second group of second through electrodes 133b for transferring power, the degree of freedom in the design of the first group of second through electrodes 133a for transferring a signal may increase.

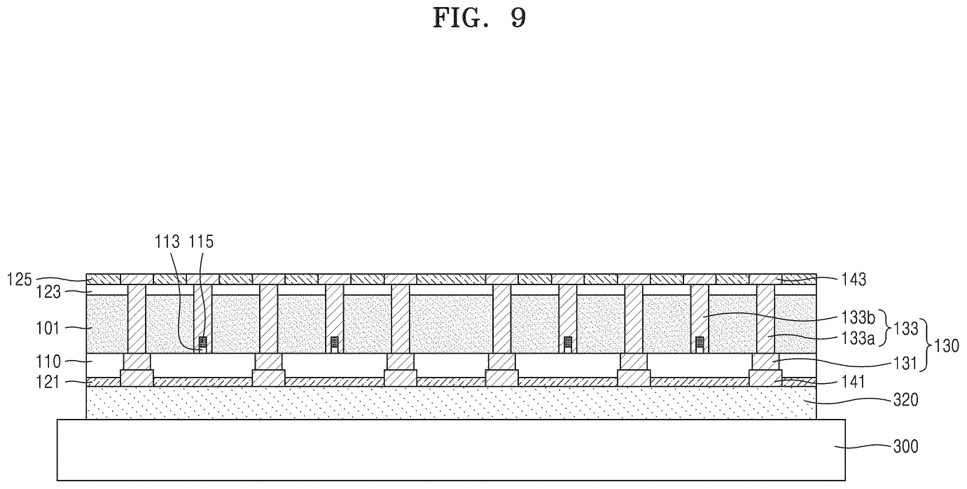

Referring to FIG. 9, the second upper protective layer 125 covering the upper surfaces of the second through electrode 133 and the first upper protective layer 123 may be formed. After forming the second upper protective layer 125, the upper pad 143 passing through the second upper protective layer 125 and connected to the second through electrode 133 may be formed.

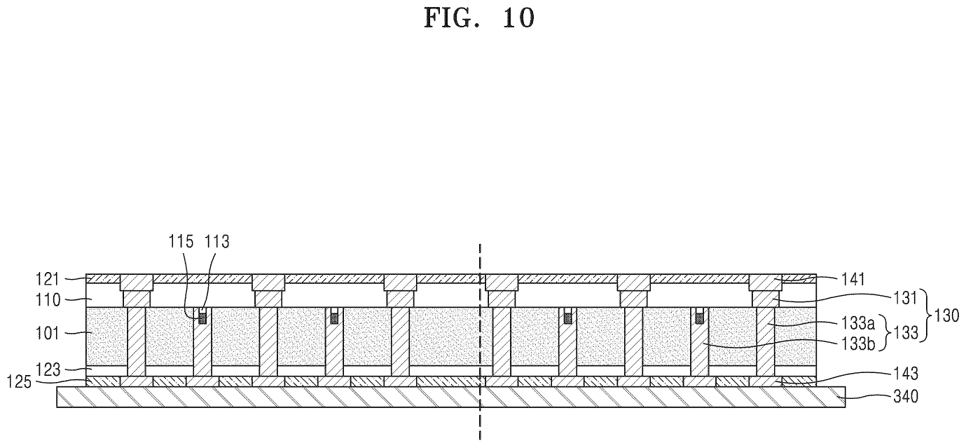

Referring to FIG. 10, the structure of FIG. 9 may be turned over and attached to a tape 340, and then the carrier substrate 300 (see FIG. 9) and the adhesive layer 320 (see FIG. 9) may be removed. Thereafter, the structure of FIG. 10 may be individualized through a dicing process. The dicing process may be performed through, for example, a plasma dicing process. However, the inventive concepts are not limited thereto, and a blade dicing process or a laser dicing process may be used for the individualization. The dicing process may be referred to as a sawing process.

Thereafter, the semiconductor device 100 of FIG. 1 may be completed by forming the connection terminal 150 on the lower pad 141. In some embodiments, when contamination of the connection terminal 150 is sufficiently prevented in the dicing process, the connection terminal 150 may be first formed, and then individualization of semiconductor chips may be performed through the dicing process.

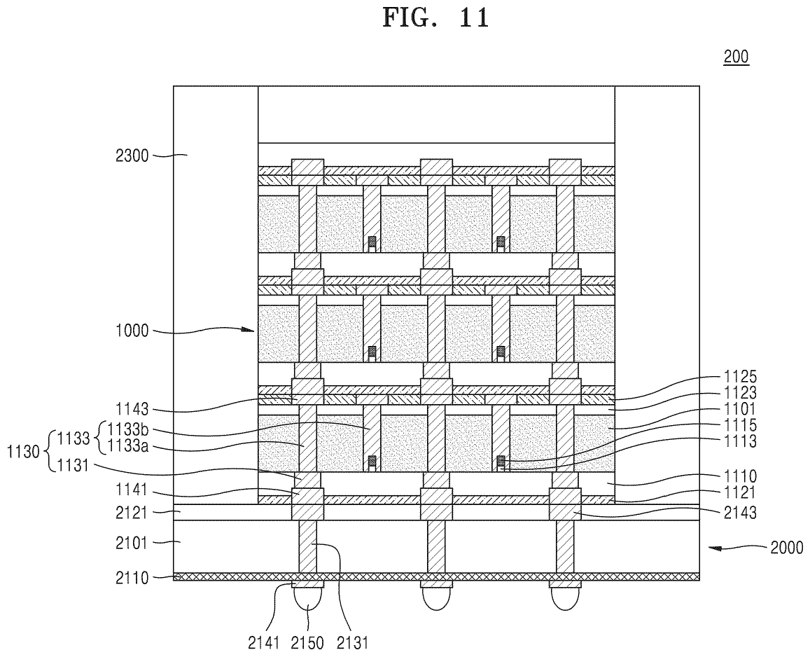

FIG. 11 is a cross-sectional view schematically illustrating a semiconductor package 200 according to at least one example embodiment. The description made with respect to the semiconductor device 100 with reference to FIGS. 1 to 3 is simply repeated or omitted.

Referring to FIG. 11, memory chips 1000 may be stacked on a base chip 2000. Although FIG. 11 shows that the semiconductor package 200 includes four memory chips 1000 stacked on the base chip 2000, the inventive concepts are not limited thereto. For example, the number of memory chips 1000 stacked on the base chip 2000 may be 2, 3, 5, or more.

As a reference, in the semiconductor package 200 of the inventive concepts, the number of memory chips 1000 may be 4n (n is a natural number). Accordingly, the semiconductor package 200 may include a multiple of four memory chips 1000, such as four, eight, or twelve memory chips 1000. In addition, every four memory chips 1000 may be tested and operated together with the same stack identification (ID). For example, when the semiconductor package 200 includes eight memory chips 1000, the first to fourth memory chips may have a first stack ID, and the fifth to eighth memory chips may have a second stack ID. However, the semiconductor package 200 of the inventive concepts are not limited to a multiple of four memory chips 1000 and stack IDs corresponding thereto. For example, the semiconductor package 200 of the inventive concepts may include a multiple of two memory chips 1000 and stack IDs corresponding thereto or include a multiple of eight memory chips 1000 and stack IDs corresponding thereto.

In some example embodiments, the memory chips 1000 may have the same horizontal size and internal structure. However, the uppermost memory chip 1000 may not include a through electrode and an upper pad. In addition, the uppermost memory chip 1000 may be thicker than each of the other memory chips 1000. In some embodiments, the total height of the semiconductor package 200 may be adjusted by adjusting the thickness of the uppermost memory chip 1000.

In some example embodiments, the base chip 2000 may be disposed beneath the memory chips 1000. The base chip 2000 may have a larger size than the memory chips 1000 disposed thereon. However, the size of the base chip 2000 is not limited thereto. For example, in some embodiments, the base chip 2000 may have substantially the same size as the memory chips 1000. In this case, the base chip 2000 may be coupled to the memory chips 1000 through hybrid copper bonding (HCB). For example, an upper connection pad 2143 and a lower pad 1142 of the lowermost memory chip 1000 may be disposed to overlap each other in the vertical direction and attached to each other.

In some example embodiments, the base chip 2000 may include a semiconductor substrate 2101, an active layer 2110, a through electrode 2131, a lower connection pad 2141, the upper connection pad 2143, and a protective layer 2121.

In some example embodiments, the semiconductor substrate 2101 may constitute a body of the base chip 2000 and include one or more semiconductors such as Si, Ge, SiGe, SiC, GaP, GaAs, GaSb, InP, and/or the like. In some embodiments, the semiconductor substrate 2101 may include an SOI substrate or a GOI substrate. For example, the semiconductor substrate 2101 may include a BOX layer.

In some example embodiments, the active layer 2110 may be provided beneath the semiconductor substrate 2101 and include an integrated circuit layer and a wiring layer. The integrated circuit layer of the active layer 2110 may include a plurality of logic devices. Accordingly, the base chip 2000 may be a logic chip. The base chip 2000 may be disposed beneath the memory chips 1000, integrate signals from the memory chips 1000 and transmit the integrated signal to the outside, and transmit a signal and power from the outside to the memory chips 1000. Accordingly, the base chip 2000 may be referred to as a buffer chip or an interface chip. As a reference, when the base chip 2000 is referred to as a buffer chip or the like, the memory chips 1000 may be referred to as a core chip.

In some embodiments, the base chip 2000 may include a controller configured to control signal transmission between the memory chips 1000 and an external device. When the base chip 2000 includes the controller, the base chip 2000 may be referred to as a logic chip, a control chip, or the like. In addition, in some embodiments, the base chip 2000 may include a power management integrated circuit (PMIC) configured to manage power or a clock.

In the semiconductor package 200 of the inventive concepts, the base chip 2000 is not limited to a buffer chip or a logic chip. For example, the base chip 2000 may include a plurality of memory devices in the integrated circuit layer of the active layer 2110. Accordingly, the base chip 2000 may include a memory chip.

In some example embodiments, the through electrode 2131 may pass through the semiconductor substrate 2101 in the vertical direction and connect the active layer 2110 to the upper connection pad 2143. The through electrode 2131 may indicate a through silicon via (TSV) but is not limited thereto. A connection bump 2150 may be disposed beneath the base chip 2000. The connection bump 2150 may be connected to the lower connection pad 2141 and thus electrically connected to the base chip 2000.

In some example embodiments, the connection bump 2150 may be disposed on the lower connection pad 2141 and connected to wirings of the wiring layer of the active layer 2110. In addition, the connection bump 2150 may be connected to the through electrode 2131 through the wirings of the wiring layer of the active layer 2110. The connection bump 2150 may be formed by a solder ball but is not limited thereto. For example, the connection bump 2150 may have a structure including a pillar and a solder. The semiconductor package 200 may be mounted on an external substrate, such as a mainboard, through the connection bump 2150.

In some example embodiments, the protective layer 2121 may cover the upper surface of the semiconductor substrate 2101. The upper connection pad 2143 may pass through the protective layer 2121 and include Cu.

In some example embodiments, in the semiconductor package 200 of the inventive concepts, each of the memory chips 1000 may include the semiconductor device 100 of FIG. 1. A semiconductor substrate 1101, an active layer 1110, a lower protective layer 1121, a first upper protective layer 1123, a second upper protective layer 1125, a through electrode 1130, the lower pad 1141, and an upper pad 1143 may be substantially the same as corresponding elements of FIG. 1, and a detailed description thereof is omitted.

In some example embodiments, the active layer 1110 may include a protrusion portion 1113 protruding in the direction of the semiconductor substrate 1101 from the upper surface of the active layer 1110 and a first metal layer 1115 covering the upper surface of the protrusion portion 1113. Herein, the first metal layer 1115 may supply power to the semiconductor substrate 1101. For example, the first metal layer 1115 may be referred to as a power rail or a power pad.

In some example embodiments, the lower protective layer 1121 may be disposed on the lower surface of each of the memory chips 1000. An upper protective layer may be disposed on the upper surface of each of the memory chips 1000. The upper protective layer may have a multi-layer structure including the first upper protective layer 1123 and the second upper protective layer 1125. The first upper protective layer 1123 may cover the upper surface of each of the memory chips 1000, and the second upper protective layer 1125 may cover the upper surface of the first upper protective layer 1123.

In some example embodiments, the lower pad 1141 may have a structure passing through the lower protective layer 1121. For example, the lower pad 1141 may have a structure fully or partially passing through the lower protective layer 1121. The lower pad 1141 may have a structure buried in the lower protective layer 1121 and be exposed from the lower surface of the lower protective layer 1121. The lower pad 1141 may be connected to the wirings of the wiring layer of the active layer 1110 or to the through electrode 1130.

In some example embodiments, the upper pad 1143 may have a structure passing through the second upper protective layer 1125. For example, the upper pad 1143 may have a structure fully or partially passing through the second upper protective layer 1125. Herein, the upper pad 1143 may have a structure partially passing through the first upper protective layer 1123. The upper pad 1143 may have a structure buried in the second upper protective layer 1125 and be exposed from the upper surface of the second upper protective layer 1125. The upper pad 1143 may be directly connected to the through electrode 1130. That is, the lower surface of the upper pad 1143 may be in contact with the upper surface of the through electrode 1130.

In some example embodiments, the through electrode 1130 may include a plurality of first through electrodes 1131 and a plurality of second through electrodes 1133. Each of the plurality of first through electrodes 1131 may pass through the active layer 1110 in the vertical direction. The lower surface of a first through electrode 1131 may be connected to the upper surface of the lower pad 1141, and the upper surface of the first through electrode 1131 may be connected to the lower surface of a second through electrode 1133. The second through electrode 1133 may pass through the semiconductor substrate 1101 in the vertical direction. Herein, the second through electrode 1133 may pass through the first upper protective layer 1123, but the inventive concepts are not limited thereto. The upper surface of the second through electrode 1133 may be connected to the lower surface of the upper pad 1143, and the lower surface of the second through electrode 1133 may be connected to the upper surface of the first through electrode 1131.

In some example embodiments, the plurality of second through electrodes 1133 may include a first group of second through electrodes 1133a and a second group of second through electrodes 1133b. A second through electrode 1133a in the first group may be connected to the first through electrode 1131. A second through electrode 1133b in the second group may be connected to the first metal layer 1115.

In some example embodiments, the second through electrode 1133b in the second group may cover the upper surface and the side surface of the first metal layer 1115. In addition, the second through electrode 133b in the second group may cover the side surface of the protrusion portion 1113 and a portion of the upper surface of the active layer 1110. The lower surface of the second through electrode 1133b in the second group may have a recessed shape corresponding to the shape of the protrusion portion 1113 and the first metal layer 1115.

In some example embodiments, the upper surfaces of the plurality of first through electrodes 1131 may be coplanar with the upper surface of the active layer 1110. In addition, the lower surfaces of the plurality of second through electrodes 1133 may be coplanar with the lower surface of the semiconductor substrate 1101.

In some example embodiments, the width of each of the plurality of first through electrodes 1131 in the horizontal direction may be different from the width of each of the plurality of second through electrodes 1133 in the horizontal direction. The width of the first through electrode 1131 in the horizontal direction may be greater than the width of the second through electrode 1133 in the horizontal direction, but the inventive concepts are not limited thereto. In addition, the width of the second through electrode 1133a in the first group in the horizontal direction may be substantially the same as the width of the second through electrode 1133b in the second group in the horizontal direction, but the inventive concepts are not limited thereto. For example, the width of the second through electrode 1133a in the first group in the horizontal direction may be different from the width of the second through electrode 1133b in the second group in the horizontal direction.

In some example embodiments, the side surface of the first through electrode 1131 may not be coplanar with the side surface of the second through electrode 1133. Because the width of the first through electrode 1131 in the horizontal direction is different from the width of the second through electrode 1133 in the horizontal direction, a step difference in the horizontal direction may be formed at the interface of the first through electrode 1131 and the second through electrode 1133.

In some example embodiments, the second through electrode 1133a in the first group may transfer a signal. The second through electrode 1133a in the first group may be connected to the first through electrode 1131 and function as a path for transferring a signal. The second through electrode 1133b in the second group may transfer power. The second through electrode 1133b in the second group may be connected to the first metal layer 1115 and function as a path for transferring power.

In some example embodiments, the memory chips 1000 may be coupled to each other through HCB. For example, every two adjacent memory chips 1000 may be attached to each other by disposing the two memory chips 1000 such that the upper pad 1143 of the lower memory chip 1000 overlaps the lower pad 1141 of the upper memory chip 1000 in the vertical direction.

A sealing material 2300 may seal the memory chips 1000 on the base chip 2000. As shown in FIG. 11, the sealing material 2300 may not cover the upper surface of the uppermost memory chip 1000. Accordingly, the upper surface of the uppermost memory chip 1000 may be exposed from the sealing material 2300. Hower, the inventive concepts are not limited thereto, and the sealing material 2300 may cover the upper surface of the uppermost memory chip 1000. The sealing material 2300 may include, for example, an epoxy mold compound (EMC), but the material of the sealing material 2300 is not limited to the EMC.

In the semiconductor package 200 of the inventive concepts, each of the memory chips 1000 may include a DRAM chip. In addition, each of the memory chips 1000 may include a DRAM chip for HBM. Accordingly, the semiconductor package 200 of the inventive concepts may be an HBM package. However, the semiconductor package 200 of the inventive concepts are not limited to the HBM package.

In the semiconductor package 200 of the inventive concepts, by respectively forming the first through electrode 1131 and the second through electrode 1133 from the front-side and the back-side of the semiconductor substrate 1101, the through electrode 1130 of which the pitch decreases and the depth increases may be formed. Accordingly, the process cost and process difficulty of the semiconductor package 200 may be reduced, and the electrical performance of the semiconductor package 200 may be improved.

In addition, by forming, from the back-side of the semiconductor substrate 1101, the second group of second through electrodes 1133b for transferring power, the degree of freedom in the design of the first group of second through electrodes 1133a for transferring a signal may increase.

While the inventive concepts have been particularly shown and described with reference to embodiments thereof, it will be understood that various changes in form and details may be made therein without departing from the spirit and scope of the following claims.

What is claimed is:

1. A semiconductor device comprising:
a semiconductor substrate;
an active layer covering a lower surface of the semiconductor substrate, the active layer comprising a protrusion portion and a first metal layer, the protrusion portion protruding from an upper surface of the active layer and the first metal layer covering an upper surface of the protrusion portion;
a plurality of first through electrodes passing through the active layer in a vertical direction; and
a plurality of second through electrodes passing through the semiconductor substrate in the vertical direction, the plurality of second through electrodes comprising
a first group of the plurality of second through electrodes respectively connected to the plurality of first through electrodes, and
a second group of the plurality of second through electrodes each connected to the first metal layer.

2. The semiconductor device of claim 1, wherein at least one of the second through electrodes in the second group covers an upper surface of the first metal layer, a side surface of the first metal layer, and a side surface of the protrusion portion.

3. The semiconductor device of claim 1, further comprising:
a first seed layer covering an upper surface and a side surface of at least one of the plurality of first through electrodes; and
a second seed layer covering a lower surface and a side surface of at least one of the plurality of second through electrodes.

4. The semiconductor device of claim 3, wherein the second seed layer covers an upper surface of the first metal layer, a side surface of the first metal layer, and a side surface of the protrusion portion.

5. The semiconductor device of claim 1, further comprising:
a barrier layer between at least one of second through electrodes in the second group and the first metal layer.

6. The semiconductor device of claim 1, wherein
lower surfaces of the plurality of second through electrodes are coplanar with the lower surface of the semiconductor substrate, and
upper surfaces of the plurality of first through electrodes are coplanar with the upper surface of the active layer.

7. The semiconductor device of claim 1, wherein the plurality of first through electrodes extend in the vertical direction to pass through a portion of the semiconductor substrate.

8. The semiconductor device of claim 1, wherein a width of each of the plurality of first through electrodes in a horizontal direction is different from a width of each of the plurality of second through electrodes in the horizontal direction.

9. The semiconductor device of claim 1, wherein each of the plurality of second through electrodes in the first group has a first width in a horizontal direction, each of the plurality of second through electrodes in the second group has a second width in the horizontal direction, and the first width is the same as the second width.

10. The semiconductor device of claim 1, wherein
a portion of a lower surface of a second through electrode in the first group is in contact with a portion of an upper surface of a first through electrode, and
a portion of a side surface of the second through electrode in the first group is in contact with a portion of a side surface of the first through electrode.

11. The semiconductor device of claim 1, wherein a central axis of a first through electrode in the vertical direction mismatches a central axis of a corresponding one of the second through electrodes in the first group in the vertical direction, the corresponding second through electrode in the first group being in contact with the first through electrode.

12. The semiconductor device of claim 1, wherein the first group of second through electrodes are configured to transfer a signal, and the second group of second through electrodes are configured to transfer power.

13. A semiconductor device comprising:
a semiconductor substrate;
an active layer covering a lower surface of the semiconductor substrate, the active layer comprising a protrusion portion and a first metal layer, the protrusion portion protruding from an upper surface of the active layer and the first metal layer covering an upper surface of the protrusion portion;
a lower protective layer covering a lower surface of the active layer;
an upper protective layer covering an upper surface of the semiconductor substrate;
a plurality of first through electrodes passing through the active layer in a vertical direction;
a plurality of second through electrodes passing through the semiconductor substrate in the vertical direction;
a plurality of lower pads respectively connected to the plurality of first through electrodes and passing through the lower protective layer; and
a plurality of upper pads respectively connected to the plurality of second through electrodes and passing through the upper protective layer,
wherein the plurality of second through electrodes comprise
a first group of the plurality of second through electrodes respectively connected to the plurality of first through electrodes and configured to transfer a signal, and
a second group of the plurality of second through electrodes each connected to the first metal layer and configured to transfer power.

14. The semiconductor device of claim 13, wherein at least one of the second through electrodes in the second group covers an upper surface of the first metal layer, a side surface of the first metal layer, and a side surface of the protrusion portion.

15. The semiconductor device of claim 13, further comprising
a first seed layer covering an upper surface and a side surface of at least one of the plurality of first through electrode; and
a second seed layer covering a lower surface and a side surface of at least one of the plurality of second through electrode.

16. The semiconductor device of claim 15, wherein a step difference in a horizontal direction is formed at an interface of one of the plurality of first through electrodes and a corresponding one of the second through electrodes in the first group.

17. The semiconductor device of claim 13, wherein one of the first through electrodes is obliquely disposed with respect to a corresponding one of the second through electrodes in the first group being in contact with the one first through electrode.

18. A semiconductor package comprising:
a base chip;
a plurality of memory chips on the base chip; and
a sealing material sealing the plurality of memory chips on the base chip,
wherein each of the plurality of memory chips comprises:
a semiconductor substrate,
an active layer covering a lower surface of the semiconductor substrate, the active layer comprising a protrusion portion and a first metal layer, the protrusion portion protruding from an upper surface of the active layer and the first metal layer covering an upper surface of the protrusion portion,
a plurality of first through electrodes passing through the active layer in a vertical direction, and
a plurality of second through electrodes passing through the semiconductor substrate in the vertical direction, and
wherein the plurality of second through electrodes comprise
a first group of the plurality of second through electrodes respectively connected to the plurality of first through electrodes and configured to transfer a signal, and a second group of the plurality of second through electrodes each connected to the first metal layer and configured to transfer power.

19. The semiconductor package of claim 18, wherein each of the plurality of memory chips includes a dynamic random access memory (DRAM) chip, and the semiconductor package includes a high bandwidth memory (HBM) package.

20. The semiconductor package of claim 18, wherein each of the plurality of first through electrodes has a first width in a horizontal direction, each of the plurality of second through electrodes has a second width in the horizontal direction, and the second width is different from the first width.
